(19) United States
(12) Patent Application Publication
(10) Pub. No.: US 2008/0009093 A1
(43) Pub. Date: Jan. 10, 2008

(54) Silicon material having a mark on the surface thereof and the method of making the same

(76) Inventors: Chen-Kuei Chung, Tainan (TW); Meng-Yu Wu, Tainan (TW); En-Jou Hsiao, Tainan (TW)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/723,508

(22) Filed: Mar. 20, 2007

(30) Foreign Application Priority Data
Jul. 7, 2006 (TW) 095124898

(51) Int. Cl. H01L 21/00

(52) U.S. Cl. 438/106

(57) ABSTRACT

The present invention relates to a silicon material having a mark on the surface thereof and the method for making the same. The method comprises the following steps: (a) providing a silicon material; (b) providing a glass substrate; (c) putting the silicon material on the glass substrate; and (d) focusing a CO₂ laser beam on the silicon material as to form a mark on the bottom surface of the silicon material, wherein the material of the mark is silicon oxide. Whereby the cheap CO₂ laser is utilized to form the mark on the silicon material, and the mark can be erased easily by a proper chemical for recycling the silicon material.

### BACKGROUND OF THE INVENTION

1. Field of the Invention

The present invention relates to a processing method of a silicon material, and more particularly, to a method for forming a mark on the surface of a silicon material.

2. Description of the Related Art

At present, laser is a marking technique widely used in the industry, and is applied to materials such as plastic, rubber, ceramics, metal, and silicon wafer. Compared with conventional manners, for example, mechanical engraving, chemical etching, screen printing, and ink printing, laser marking has the advantages of rapid production, high flexibility, and being controllable via a computer system. In addition, a prominent characteristic of laser marking is the permanence of the mark generated by a laser on the surface of a workpiece.

There are many kinds of lasers and the femtosecond laser, excimer laser, or Nd:YAG laser are mostly used in silicon wafer marking. However, these lasers are generally very expensive, and the processing mechanism thereof is ablating the surface of the silicon wafer with a laser beam of high energy, which may damage the surface structure of the silicon wafer and result in many flying minute particles, i.e., the so-called “splashing fragments”. The fragments are prone to be attached to the silicon wafer, thus becoming difficult to erase. When proceeding to the subsequent device circuit process, a grip head is used to fix the edge of the silicon wafer. However, the clamping force is easy to make the residual fragments fall off and cause another splashing, which not only contaminates the process, but also severely affects the yield and quality of the product. Moreover, these lasers remove the surface of the product to form a mark, so the mark cannot be re-made, and once marked incorrectly, the product will be abandoned for uselessness, and the material cannot be recycled.

Moreover, in the conventional fabrication process of semiconductor devices, the marking process is generally performed after the silicon wafer is diced into chips. As the technique is being constantly updated and the integrated circuits are becoming lighter, thinner, and smaller, the processing technique has also evolved into dicing the wafer after marking, so as to improve the efficiency of production and operation. However, as the size of the silicon wafer is getting larger, the thickness thereof stays unchanged or becomes smaller. Therefore, when the surface of the silicon wafer is ablated with a laser beam of high energy, a large amount of stress is easily accumulated on the surface of the silicon wafer, resulting in deformation and warping thereof. Though the stress can be eliminated by high temperature annealing, the basic property of the silicon wafer is greatly affected, which is disadvantageous for the subsequent production.

In view of the disadvantages of using the above lasers, ROC (TW) Patent Publication No. 350797 provides a processing method for removing particles in the semiconductor industry, and particularly for removing silicon particles generated after making a mark with a laser on the chip. In the method, the wetting and catalytic effects are achieved with the hydroxyl in the aqueous ammonia, so as to oxidize the particles. ROC (TW) Patent Publication No. 434749 provides a marking method, in which the wafer mark can be recovered after a chemical-mechanical polishing process is performed on the wafer, and no silicon particles are generated during the marking. According to the method, the photoresist is exposed with a fiber optic cable, so as to form a mark on the photoresist, and a wafer mark is formed subsequently by etching with the photoresist having a mark formed thereon as a mask. ROC (TW) Patent Publication No. 359885 provides a method, in which a mark pattern on a tape is defined with a laser beam, then the tape is adhered onto a silicon wafer, then the pattern is transferred to the wafer by a wet or dry process, and the tape is finally stripped to finish making a mark on the silicon wafer. The above method can avoid causing splashing fragments.

In Japanese Patent Publication No. 11-260675, a spot-shaped mark is fabricated on a silicon wafer with a laser, and a layer of transparent thin film is formed thereon. When a laser beam passes through the transparent thin film to make the spot-shaped mark regionally melt and deformed, a plurality of spot-shaped marks can be formed. This method can prevent the splashing fragments generated during the laser processing from being attached to the silicon wafer, and the definition and visibility are ensured by the shape of these spot-shaped marks.

ROC (TW) Patent Publication No. I233197 provides a chip scale mark and a marking method of the same. According to the method, when a laser beam ablates the surface of a silicon wafer, the chip size mark is used to stably keep the laser system and the marking distance between the wafers by removing the wafer warp on the wafer support. ROC (TW) Patent Publication No. 200538304 provides a method for making a mark by forming an interference fringe on a body to be marked with a laser beam.

Therefore, it is necessary to provide a method for forming a mark on the surface of a silicon material to solve the above problems.

### SUMMARY OF THE INVENTION

An objective of the present invention is to provide a method for forming a mark on the surface of a silicon material. The method includes the following steps: (a) providing a silicon material, which has a top surface and a bottom surface; (b) providing a glass substrate, which has a top surface; (c) disposing the bottom surface of the silicon material on the top surface of the glass substrate; and (d) focusing a CO₂ laser on the silicon material, so as to form a mark on the bottom surface of the silicon material. The material of the mark is silicon oxide.

Another objective of the present invention is to provide a method for forming a mark on the surface of a silicon material. The method includes the following steps: (a) providing a silicon material, which has a top surface and a bottom surface; (b) providing a substrate, which has a top surface; (c) forming a metal film on the top surface of the substrate; (d) disposing the bottom surface of the silicon material on the top surface of the substrate; and (e) focusing a CO₂ laser on the silicon material, so as to form a mark on the bottom surface of the silicon material. The material of the mark is metal and oxide.

In the present invention, the property that the silicon material fails to absorb the CO₂ laser with a light wavelength of 10.6 μm can be successfully changed by attaching a glass substrate or a substrate having a metal film coated glass substrate to the silicon material, thereby achieving the purpose of making a mark. The CO₂ laser is the cheapest laser among various lasers, so the present invention provides a method for marking the front and back sides of the wafer in a rapid and simple way, which costs less, consumes less energy, and has high reliability and quality. Moreover, stress can be avoided by utilizing low energy means of marking, such that the silicon material will not be deformed or warped. Further, the present invention does not utilize the laser beam in such a way of ablation, therefore the wafer will not be damaged after the processing, and no splashing fragments and dusts will be generated, thereby abating pollution and improving yield. Besides, it is not necessary to use a mask, and the photolithography process may not be affected, such that the capacity is improved. Additionally, when marked incorrectly with other lasers, the surface of the wafer product is usually damaged. However, in the present invention, a CO₂ laser is employed, and a common chemical can be used to erase the incorrect mark so that the silicon material may be recycled.

### BRIEF DESCRIPTION OF THE DRAWINGS

FIG. 1 is a schematic diagram of a first embodiment of a method for forming a mark on the surface of a silicon material according to the present invention;

FIG. 2 is a photograph of the silicon material having a mark on the surface thereof formed according to the first embodiment of the present invention, in which the mark is constituted by letters;

FIG. 3 is a photograph of the silicon material having a mark on the surface thereof formed according to the first embodiment of the present invention, in which the mark is constituted by totems and random codes;

FIG. 4 is a schematic diagram of a second embodiment of a method for forming a mark on the surface of a silicon material according to the present invention; and

FIG. 5 is a schematic diagram of a third embodiment of a method for forming a mark on the surface of a silicon material according to the present invention.

### DETAILED DESCRIPTION OF THE INVENTION

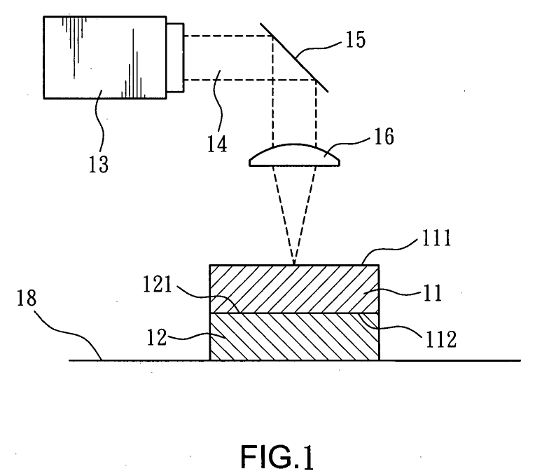

FIG. 1 is a schematic diagram of a method for forming a mark on the surface of a silicon material according to a first embodiment of the present invention. In this embodiment, firstly, a silicon material 11 is provided, which has a top surface 111 and a bottom surface 112. In this embodiment, the silicon material 11 is a silicon wafer, which can be pure silicon or have a multi-layered thin film. Additionally, the silicon material 11 can also be a silicon chip. In this embodiment, the silicon wafer is disposed with a polished surface facing upward (i.e., the top surface 111 of the silicon wafer is a polished surface) or with a rough surface facing upward (i.e., the bottom surface 112 of the silicon wafer is a polished surface). Alternatively, the silicon wafer can be a double-side polished silicon wafer (i.e., the top surface 111 and the bottom surface 112 of the silicon wafer both are polished surfaces). Preferably, the bottom surface 112 of the silicon wafer is a polished surface.

Next, a glass substrate 12 is provided, which has a top surface 121. Afterward, the bottom surface 112 of the silicon material 11 is disposed on the top surface 121 of the glass substrate 12, and the top surface 121 of the glass substrate 12 is closely attached to the bottom surface 112 of the silicon material 11. In this embodiment, a clamp (not shown) is used to clamp the glass substrate 12 and the silicon material 11, such that the top surface 121 of the glass substrate 12 is closely attached to the bottom surface 112 of the silicon material 11.

Next, the glass substrate 12 and the silicon material 11 are disposed on a support platform 18.

After that, a CO₂ laser 14 is provided by a CO₂ laser generator 13. Finally, the CO₂ laser 14 is focused on the silicon material 11 through a focusing mechanism having a reflecting mirror 15 and a focusing lens 16, so as to form a mark on the bottom surface 112 of the silicon material 11, in which the CO₂ laser 14 can be focused on the interior, the top surface 111, or the bottom surface 112 of the silicon material 11. The focusing position of the CO₂ laser 14 can be adjusted with the reflecting mirror 15 and the focusing lens 16, or controlled by adjusting the direction of Z-axis of the support platform 18, and the two methods for adjusting focusing position can be integrated. In this embodiment, the CO₂ laser 14 is focused on the top surface 111 of the silicon material 11. By adjusting appropriate laser processing parameters, such as, the energy of the CO₂ laser source, scan times (about less than five times), and together by scanning the laser spot or moving the support platform 18, a desired mark shape can be achieved.

In this embodiment, the mark is not a curved groove, but a silicon oxide formed by growing or depositing, which is formed by the re-solidification of the oxidized or melt glass silicon oxide generated by the silicon material 11 under the temperature of the CO₂ laser 14. Moreover, the mark can be of any shape, such as a numeral, a letter, or a totem. Therefore, if a part or the whole of the mark is undesired or incorrect, a cleaning chemical can be used to directly erase the mark. The chemical cleaning agent can be hydrofluoric acid (HF), buffered oxide etching (BOE), or a general chemical capable of erasing oxide.

In the present invention, the silicon material 11 is processed by the CO₂ laser 14. Under a normal condition, the CO₂ laser 14 that has a light wavelength of 10.6 μm cannot process the silicon material 11 that does not fall in the absorption band thereof. Therefore, in this embodiment, the property that the silicon material 11 does not absorb the CO₂ laser with a light wavelength of 10.6 μm can be successfully changed by attaching the glass substrate 12 to the silicon material 11, thereby achieving the purpose of marking. The present invention has the following advantages: 1. the CO₂ laser is the cheapest laser among various lasers; 2. the present invention provides a method for marking the front and back sides of the water in a rapid and simple way, which costs less, consumes less energy, and has high reliability and quality; 3. stress can be avoided by utilizing low energy, such that the silicon material 11 will not be deformed or warped; 4. the present invention does not adopt the laser beam in the manner of ablation, such that the wafer will not be damaged after the processing, and no splashing fragments and dusts will be generated, thereby abating pollution and improving the yield; 5. it is not necessary to use a mask, and the photolithography process may not be affected, such that the capacity is improved; 6. the silicon material 11 can be a silicon wafer of pure silicon, and can also be a silicon wafer with a multi-layered thin film; 7. when marked incorrectly, as other lasers are used in the conventional art, the incorrect mark cannot be erased from the surface of the damaged product (for example, a groove is resulted). However, in the present invention, a CO₂ laser is used to generate a mark of silicon oxide, and a common chemical can be used to erase the incorrect mark for recycling the silicon material 11.

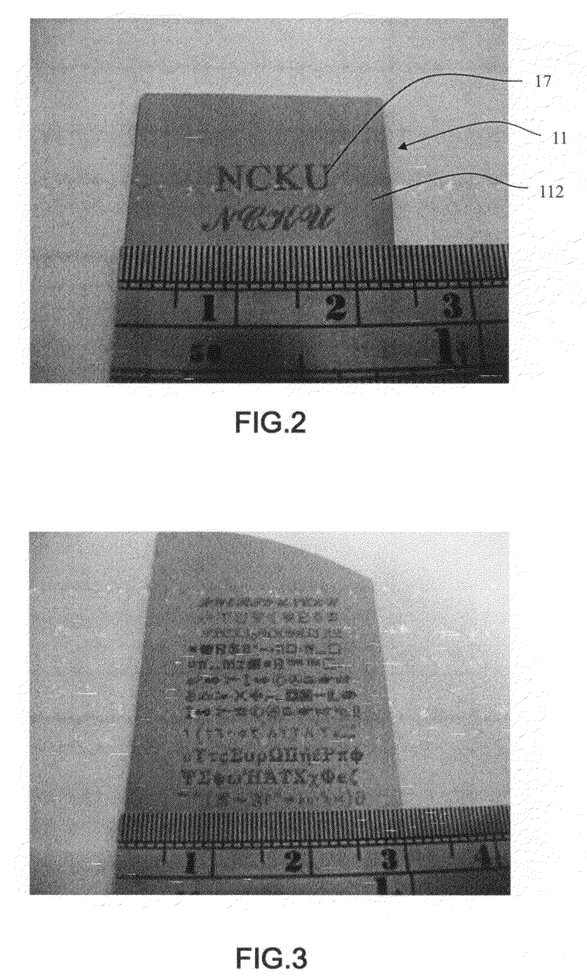

The processing condition of this embodiment is: the thicknesses of the silicon material 11 and the glass substrate 12 are both 500 μm; the power of the CO₂ laser 14 is 21 W and the focus point thereof is set on the top surface 111 of the silicon material 11; a mark is formed by directly photo-deposition once at a processing speed of 5 mm/sec, and the processing result is shown in FIG. 2.

FIG. 2 is a photograph of the silicon material having a mark on the surface thereof formed according to the first embodiment of the present invention. The silicon material having a mark according to the present invention includes a silicon material 11 and a mark 17. The silicon material 11 has a surface 112 (i.e., the bottom surface 112 in FIG. 1). In this embodiment, the surface 112 is a polished surface, and it is to be understood that the surface 112 can also be a rough surface. The mark 17 is located on the surface 112 of the silicon material 11, and the mark 17 is silicon oxide, which can be constituted by numerals, letters, or totems. In this embodiment, the silicon material 11 is a silicon wafer or a silicon chip, which can be pure silicon or have a multi-layered thin film. In this embodiment, the mark 17 is constituted by letters of “NCKU.” In other applications, the mark is other totems, or random codes, as shown in FIG. 3.

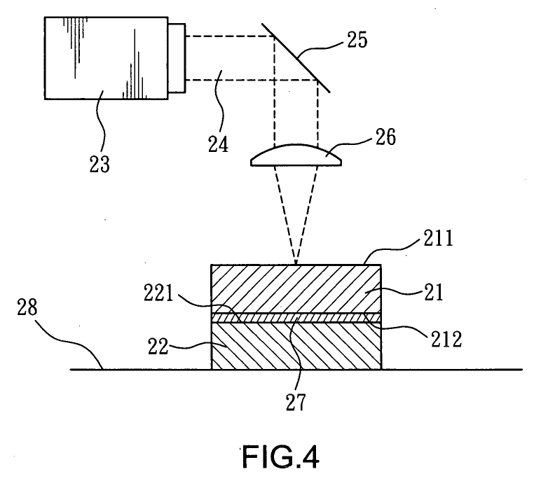

FIG. 4 is a schematic diagram of a method for forming a mark on the surface of a silicon material according to a second embodiment of the present invention. In this embodiment, firstly, a silicon material 21 is provided, which has a top surface 211 and a bottom surface 212. In this embodiment, the silicon material 21 is a silicon wafer, which can be pure silicon or have a multi-layered thin film. Additionally, the silicon material 21, can also be a silicon chip. In this embodiment, the silicon wafer is disposed with a polished surface facing upward (i.e., the top surface 211 of the silicon wafer is a polished surface) or a rough surface facing upward (i.e., the bottom surface 212 of the silicon wafer is a polished surface). Alternatively, the silicon wafer can be a double-side polished silicon wafer (i.e., the top surface 211 and the bottom surface 212 of the silicon wafer both are polished surfaces). Preferably, the bottom surface 212 of the silicon wafer is a polished surface.

Next, a glass substrate 22 is provided, which has a top surface 221. Afterward, a metal film 27 is formed on the top surface 221 of the glass substrate 22. Preferably, the metal film 27 is formed on the top surface 221 of the glass substrate 22 by coating, and the material of the metal film 27 can be selected from a group consisting of aluminum, titanium, chromium, tantalum, nickel, iron, cobalt, vanadium, tungsten, zirconium, zinc, copper, silver, and gold. The thickness of the metal film 27 is between 10-1000 nm. Preferably, the material of the metal film 27 is aluminum, titanium, chromium, tantalum, nickel, iron, cobalt, vanadium, tungsten, zirconium or zinc, and the thickness thereof is between 30-80 nm.

Afterward, the bottom surface 212 of the silicon material 21 is disposed on the metal film 27 coated glass substrate 22. And the top surface 221 of the glass substrate 22, the metal film 27, and the bottom surface 212 of the silicon material 22 are closely attached. In this embodiment, a clamp (not shown) is used to clamp the glass substrate 22 and the silicon material 21.

Next, the glass substrate 22 and the silicon material 21 are disposed on a support platform 28.

Afterward, a CO₂ laser 24 is provided by a CO₂ laser generator 23. Finally, the CO₂ laser 24 is focused on the silicon material 21 through a focusing mechanism having a reflecting mirror 25 and a focusing lens 26, so as to form a mark on the bottom surface 211 of the silicon material 21, in which the CO₂ laser 24 can be focused on the interior, the top surface 211, or the bottom surface 212 of the silicon material 21. In this embodiment, the CO₂ laser 24 is focused on the top surface 211 of the silicon material 21. In this embodiment, the mark is not a curved groove, but a metal and oxide formed by growing or depositing, which are formed by utilizing the temperature of the CO₂ laser to melt the metal film 27 and the top surface 221 of the glass substrate 22, and re-solidifying the same, or to oxidize the metal film 27 with the silicon material 21. Moreover, the mark can be of any shape, such as a numeral, a letter, or a totem. Therefore, if a part or the whole of the mark is undesired or incorrect, an appropriate cleaning chemical can be used to directly erase the mark. The chemical can be HF, BOE, or a general chemical capable of erasing metal and oxide.

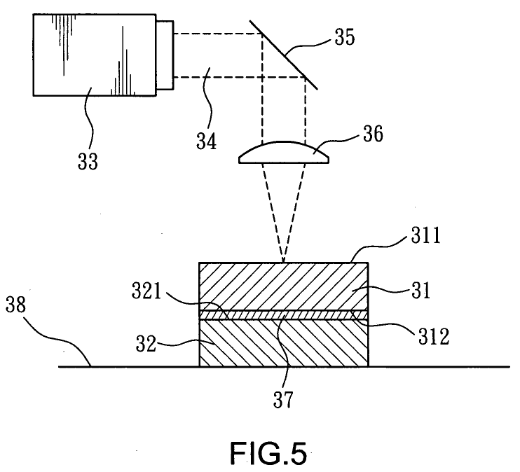

FIG. 5, is a schematic diagram of a method for forming a mark on the surface of a silicon material according to a third embodiment of the present invention. In this embodiment, firstly, a silicon material 31 is provided, which has a top surface 311 and a bottom surface 312. In this embodiment, the silicon material 31 is a silicon wafer, which can be pure silicon or have a multi-layered thin film. Additionally, the silicon material 31 can also be a silicon chip. In this embodiment, the silicon wafer is disposed with a polished surface facing upward (i.e., the top surface 311 of the silicon wafer is a polished surface) or with a rough surface facing upward (i.e., the bottom surface 312 of the silicon wafer is a polished surface). Alternatively, the silicon wafer can be a double-side polished silicon wafer (i.e., the top surface 311 and the bottom surface 312 of the silicon wafer both are polished surfaces). Preferably, the bottom surface 312 of the silicon wafer is a polished surface.

Next, a substrate 32 is provided, which has a top surface 321, and the material thereof is a material having low thermal conductivity except glass; for example, metal oxide, ceramics, or polymethyl methacrylate (PMMA). And then, a metal film 37 is formed on the top surface 321 of the substrate 32. Preferably, the metal film 37 is formed on the top surface 321 of the substrate 32 by coating. The material of the metal film 37 can be selected from a group consisting of aluminum, titanium, chromium, tantalum, nickel, iron, cobalt, vanadium, tungsten, zirconium, zinc, copper, silver, and gold, and the thickness of the metal film 37 is between 10-1000 nm. Preferably, the material of the metal film 37 is aluminum, titanium, chromium, tantalum, nickel, iron, cobalt, vanadium, tungsten, zirconium or zinc, and the thickness thereof is between 30-80 nm.

Next, the bottom surface 312 of the silicon material 31 is disposed on the metal film 37 of the top surface 321 of the substrate 32. And the top surface 321 of the substrate 32, the metal film 37, and the bottom surface 312 of the silicon material 31 are closely attached. In this embodiment, a clamp (not shown) is used to clamp the glass substrate 32 and the silicon material 31.

Afterward, the glass substrate 32 and the silicon material 31 are disposed on a support platform 38.

Afterward, a CO₂ laser 34 is provided by a CO₂ laser generator 33. Finally, the CO₂ laser 34 is focused on the silicon material 31 through a focusing mechanism having a reflecting mirror 35 and a focusing lens 36, so as to form a mark on the bottom surface 312 of the silicon material 31, in which the CO₂ laser 34 can be focused on the interior, the top surface 311, or the bottom surface 312 of the silicon material 31. In this embodiment, the CO₂ laser 34 is focused on the top surface 311 of the silicon material 31. In this embodiment, the mark is not a curved groove, but a metal and oxide are formed by growing or depositing, which are formed by utilizing the temperature of the CO₂ laser 34 to melt the metal film 37 and the top surface 321 of the glass substrate 32, and re-solidifying the same, or to oxidize the metal film 37 with the silicon material 31. Moreover, the mark can be of any shape, such as a numeral, a letter, or a totem. Therefore, if a part or the whole of the mark is undesired or incorrect, an appropriate cleaning chemical can be used to directly erase the mark. The chemical can be HF, BOE, or a general chemical capable of erasing metal and oxide.

While several embodiments of the present invention have been illustrated and described, various modifications and improvements can be made by those skilled in the art. The embodiments of the present invention are therefore described in an illustrative but not restrictive sense. It is intended that the present invention should not be limited to the particular forms as illustrated, and that all modifications which maintain the spirit and scope of the present invention are within the scope as defined in the appended claims.

What is claimed is:

1. A method for forming a mark on the surface of a silicon material, comprising:
(a) providing a silicon material, wherein the silicon material has a top surface and a bottom surface;
(b) providing a glass substrate, wherein the glass substrate has a top surface;
(c) disposing the bottom surface of the silicon material on the top surface of the glass substrate; and
(d) focusing a CO₂ laser on the silicon material, so as to form a mark on the bottom surface of the silicon material, wherein the material of the mark is silicon oxide.

2. The method as claimed in claim 1, wherein the silicon material is a silicon wafer.

3. The method as claimed in claim 1, wherein the silicon material is a silicon chip.

4. The method as claimed in claim 2, wherein the silicon wafer is pure silicon.

5. The method as claimed in claim 2, wherein the silicon wafer has a multi-layered thin film.

6. The method as claimed in claim 2, wherein the top surface of the silicon wafer is a polished surface.

7. The method as claimed in claim 2, wherein the bottom surface of the silicon wafer is a polished surface.

8. The method as claimed in claim 1, further comprising a step of forming a metal film on the top surface of the glass substrate after Step (b).

9. The method as claimed in claim 8, wherein the metal film is formed on the top surface of the glass substrate by coating.

10. The method as claimed in claim 8, wherein the material of the metal film is selected from a group consisting of aluminum, titanium, chromium, tantalum, nickel, iron, cobalt, vanadium, tungsten, zirconium, zinc, copper, silver, and gold.

11. The method as claimed in claim 1, wherein in Step (d), the CO₂ laser is focused on the interior, the top surface, or bottom surface of the silicon material.

12. The method as claimed in claim 1, wherein in Step (d), the mark is constituted by numerals, letters, or totems.

13. The method as claimed in claim 1, further comprising a step of erasing a part of the mark with a chemical after Step (d).

14. The method as claimed in claim 13, wherein the chemical is hydrofluoric acid (HF) or buffered oxide etching (BOE).

15. A method for forming a mark on the surface of a silicon material, comprising:
(a) providing a silicon material, wherein the silicon material has a top surface and a bottom surface;
(b) providing a substrate, wherein the substrate has a top surface;
(c) forming a metal film on the top surface of the substrate;
(d) disposing the bottom surface of the silicon material on the metal film of the top surface of the substrate; and
(e) focusing a CO₂ laser on the silicon material, so as to form a mark on the bottom surface of the silicon material, wherein the material of the mark is metal and oxide.

16. The method as claimed in claim 15, wherein the silicon material is a silicon wafer.

17. The method as claimed in claim 15, wherein the silicon material is a silicon chip.

18. The method as claimed in claim 16, wherein the silicon wafer is pure silicon.

19. The method as claimed in claim 16, wherein the silicon wafer has a multi-layered thin film.

20. The method as claimed in claim 16, wherein the top surface of the silicon wafer is a polished surface.

21. The method as claimed in claim 16, wherein the bottom surface of the silicon wafer is a polished surface.

22. The method as claimed in claim 15, wherein the material of the substrate is selected from a group consisting of metal oxide, ceramics, and polymethyl methacrylate (PMMA).

23. The method as claimed in claim 15, wherein in Step (c), the metal film is formed on the top surface of the substrate by coating.

24. The method as claimed in claim 15, wherein the material of the metal film is selected from a group consisting of aluminum, titanium, chromium, tantalum, nickel, iron, cobalt, vanadium, tungsten, zirconium, zinc, copper, silver, and gold.

25. The method as claimed in claim 15, wherein in Step (e), the CO₂ laser is focused on the interior, the top surface, or bottom surface of the silicon material.

26. The method as claimed in claim 15, wherein in Step (e), the mark is constituted by numerals, letters, or totems.

27. The method as claimed in claim 15, further comprising a step of erasing a part of the mark with a chemical after Step (e).

28. The method as claimed in claim 27, wherein the chemical is metal etching, HF, or BOE.

29. A silicon material having a mark on the surface thereof, comprising:
a silicon material, having a surface; and
a mark, located on the surface of the silicon material, wherein the mark is formed by a CO₂ laser, and the material thereof is metal or silicon oxide.

30. The silicon material as claimed in claim 29, wherein the silicon material is a silicon wafer.

31. The silicon material as claimed in claim 29, wherein the silicon material is a silicon chip.

32. The silicon material as claimed in claim 30, wherein the silicon wafer is pure silicon.

33. The silicon material as claimed in claim 30, wherein the silicon wafer has a multi-layered thin film.

34. The silicon material as claimed in claim 30, wherein the surface of the silicon wafer is a polished surface.

35. The silicon material as claimed in claim 29, wherein the mark is constituted by numerals, letters, or totems.
